(19) United States
(12) Patent Application Publication
(10) Pub. No.: US 2025/0295008 A1
(43) Pub. Date: Sep. 18, 2025

(54) METHOD FOR FABRICATING DISPLAY DEVICE

(71) Applicant: Samsung Display Co., LTD., Yongin-si (KR)

(72) Inventors: Gi Hyun LEE, Yongin-si (KR); Jin Seok CHOI, Yongin-si (KR)

(21) Appl. No.: 19/002,405

(22) Filed: Dec. 26, 2024

(30) Foreign Application Priority Data
Mar. 12, 2024 (KR) 10-2024-0034601

(51) Int. Cl. H10K 59/80; H10K 59/12

(52) U.S. Cl. CPC H10K 59/873; H10K 59/1201; H10K 59/8791

(57) ABSTRACT

In a method for fabricating a display device, the method includes: loading a substrate; forming a light-emitting element layer on the substrate; forming a capping layer on the light-emitting element layer; forming a first encapsulation film on the capping layer; forming a thin-film encapsulation layer by forming second and third encapsulation films on the first encapsulation film; attaching a polarizer on the thin-film encapsulation layer; and measuring first optical characteristics of the light-emitting element layer prior to the forming the capping layer, wherein measuring the optical characteristics comprises measuring and determining a white angle difference (WAD) distribution of the light-emitting element layer to send a feed forward signal in order to adjust a thickness of the first encapsulation film.

### CROSS-REFERENCE TO RELATED APPLICATION

The present application claims priority to and the benefit of Korean Patent Application No. 10-2024-0034601 filed on Mar. 12, 2024 in the Korean Intellectual Property Office, the entire disclosure of which is incorporated herein by reference.

### BACKGROUND

### 1. Field

Aspects of some embodiments of the present disclosure relate to a display device and a method for fabricating the same.

### 2. Description of the Related Art

As the information-oriented society evolves, various demands for display devices are ever increasing. For example, display devices are being employed by a wide variety of electronic devices such as smart phones, digital cameras, laptop computers, navigation devices, and smart televisions.

Display devices may be flat panel display devices such as liquid-crystal display devices, field emission display devices, and light-emitting display devices. Light-emitting display devices include, for example, an organic light-emitting display device including organic light-emitting elements, an inorganic light-emitting display device including inorganic light-emitting elements such as inorganic semiconductor, and a micro light-emitting display device including micro light-emitting elements.

An organic light-emitting element may include two opposing electrodes and a light emitting layer interposed therebetween. Electrons and holes supplied from the two electrodes are recombined in the light emitting layer to generate excitons, and the generated excitons relax from the excited state to the ground state so that light can be emitted.

An organic light-emitting display device including organic light-emitting elements requires no separate light source such as a backlight unit, and thus it consumes less power and can be made light and thin, as well as exhibiting high-quality characteristics such as wide viewing angle, high luminance and contrast, and fast response speed. Accordingly, an organic light-emitting display device is attracting attention as the next generation display device.

The above information disclosed in this Background section is only for enhancement of understanding of the background and therefore the information discussed in this Background section does not necessarily constitute prior art.

### SUMMARY

Aspects of some embodiments of the present disclosure include a method for fabricating a display device that can relatively improve display quality.

It should be noted that the characteristics of embodiments according to the present disclosure are not limited to the above-mentioned characteristics; and other characteristics of embodiments according to the present disclosure will be apparent to those skilled in the art from the following descriptions.

According to some embodiments of the present disclosure, a method for fabricating a display device, the method comprises loading a substrate, forming a light-emitting element layer on the substrate, forming a capping layer on the light-emitting element layer, forming a first encapsulation film on the capping layer, forming a thin-film encapsulation layer by forming second and third encapsulation films on the first encapsulation film, attaching a polarizer on the thin-film encapsulation layer, and measuring first optical characteristics of the light-emitting element layer prior to the forming the capping layer, wherein the measuring the optical characteristics comprises measuring and determining a white angle difference (WAD) distribution of the light-emitting element layer to send a feed forward signal in order to adjust a thickness of the first encapsulation film.

According to some embodiments, the loading the substrate comprises loading the substrate having a plurality of pixel electrodes formed thereon into a deposition equipment.

According to some embodiments, the forming the light-emitting element layer comprises forming a light emitting layer on the pixel electrodes and forming a common electrode on the light emitting layer.

According to some embodiments, the measuring the optical characteristics comprises measuring the WAD distribution of white light of the light-emitting element layer.

According to some embodiments, the measuring the optical characteristics comprises: determining whether the WAD distribution lies within a normal specification range, and sending a feed forward signal to adjust the thickness of the first encapsulation film if it is determined that it does not.

According to some embodiments, if it is determined that the WAD distribution partially deviates from the normal specification range to a particular color region, the thickness of the first encapsulation film is adjusted to move the WAD distribution to the normal specification range.

According to some embodiments, the adjusting the thickness of the first encapsulation film comprises increasing or decreasing the thickness of the first encapsulation film.

According to some embodiments, the measuring the optical characteristics comprises using a spectroscope.

According to some embodiments, the method further comprises measuring a thickness of the light-emitting element layer prior to the forming the capping layer, wherein the light-emitting element layer comprises a light emitting layer comprising a first functional layer, an organic light-emitting layer, and a second functional layer.

According to some embodiments, the measuring the thickness of the light-emitting element layer comprises measuring a thickness of each of the first functional layer, the organic light-emitting layer and the second functional layer and comparing input thicknesses with the actually formed thicknesses to send a feedback signal to the forming the light-emitting element layer.

According to some embodiments, the method further comprises measuring second optical characteristics and measuring optical characteristics of the polarizer between the forming the thin-film encapsulation layer and the attaching the polarizer.

According to some embodiments, the measuring the second optical characteristics comprises measuring the WAD distribution of white light of the light-emitting element layer on the thin-film encapsulation layer.

According to some embodiments, if it is determined that the WAD distribution partially deviates from the normal specification range to a particular color region, polarizers prepared in the measuring the optical characteristics of the polarizer are selected to move the WAD distribution to the normal specification range.

According to some embodiments, the prepared polarizers are selected by considering color coordinates and chromaticity deviations.

According to some embodiments of the present disclosure, a method for fabricating a display device, the method comprises loading a substrate, forming a light-emitting element layer on the substrate, forming a capping layer on the light-emitting element layer, forming a thin-film encapsulation layer on the capping layer, attaching a polarizer on the thin-film encapsulation layer, and measuring optical characteristics and measuring optical characteristics of a polarizer between the forming the thin-film encapsulation layer and the attaching the polarizer, wherein the measuring the optical characteristics comprises measuring and determining WAD distribution of the light-emitting element layer to send a feed forward signal in order to select polarizers.

According to some embodiments, the measuring the optical characteristics comprises measuring the WAD distribution of white light of the light-emitting element layer on the thin-film encapsulation layer.

According to some embodiments, if it is determined that the WAD distribution partially deviates from the normal specification range to a particular color region, the prepared polarizers are selected to move the WAD distribution to the normal specification range.

According to some embodiments, the prepared polarizers in the measuring the optical characteristics of the polarizer are selected by considering color coordinates and chromaticity deviations.

According to some embodiments, the method further comprises measuring a thickness of the thin-film encapsulation layer prior to the attaching the polarizer.

According to some embodiments, the measuring the thickness of the light-emitting element layer comprises: measuring the thickness of the thin-film encapsulation layer and comparing an input thickness with an actually formed thickness to send a feedback signal to the forming the thin-film encapsulation layer.

According to some embodiments of the present disclosure, an electronic device may comprise, a display device configured to provide an image, a processor configured to provide an image data signal to the display device, a memory configured to store a data information for operation, and a power moduel configured to generate power, wherein the display device is manufactured by: loading a substrate, forming a light-emitting element layer on the substrate, forming a capping layer on the light-emitting element layer, forming a first encapsulation film on the capping layer, forming a thin-film encapsulation layer by forming second and third encapsulation films on the first encapsulation film, attaching a polarizer on the thin-film encapsulation layer; and measuring first optical characteristics of the light-emitting element layer prior to the forming the capping layer, wherein measuring the first optical characteristics comprises measuring and determining a white angle difference (WAD) distribution of the light-emitting element layer to send a feed forward signal in order to adjust a thickness of the first encapsulation film.

According to some embodiments of the present disclosure, a method for fabricating a display device may include measuring WAD distribution after fabricating a light-emitting element layer; and adjusting the thickness of a first encapsulation film or a polarizer by sending a feedforward signal. Accordingly, the color difference depending on the viewing angle can be mitigated by adjusting the WAD distribution of the display device, thereby relatively improving the display quality.

It should be noted that the characteristics of embodiments according to the present disclosure are not limited to those described above and other characteristics of embodiments according to the present disclosure will be apparent to those skilled in the art from the following descriptions.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a plan view of a display device according to some embodiments of the present disclosure.

FIG. 2 is a perspective view showing a display device included in an electronic device according to some embodiments of the present disclosure.

FIG. 3 is a cross-sectional view of the display device of FIG. 2 seen from the side.

FIG. 4 is a plan view showing a display layer of a display device according to some embodiments of the present disclosure.

FIG. 5 is a cross-sectional view showing a portion of a display device according to some embodiments of the present disclosure.

FIG. 6 is a flowchart for illustrating a method for fabricating a display device according to some embodiments of the present disclosure.

FIGS. 7 and 8 are cross-sectional views showing processing operations of a method for fabricating a display device according to some embodiments of the present disclosure.

FIG. 9 is a flowchart for illustrating a method for fabricating a display device according to some embodiments.

FIG. 10 is a cross-sectional view for illustrating processing operations of a method for fabricating a display device according to some embodiments of the present disclosure.

FIG. 11 is a flowchart for illustrating a method for fabricating a display device according to some embodiments of the present disclosure.

FIG. 12 is an xy color coordinate system showing the white angle difference (WAD) distributions of display devices before improvement.

FIG. 13 is an xy color coordinate system showing the WAD distributions of display devices after improvement.

FIG. 14 is a block diagram of an electronic device according to one embodiment of the present disclosure.

FIG. 15 is a schematic diagram of an electronic device according to various embodiments of the present disclosure.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will more fully convey the scope of embodiments according to the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, aspects of some embodiments of the present disclosure will be described in more detail with reference to the accompanying drawings.

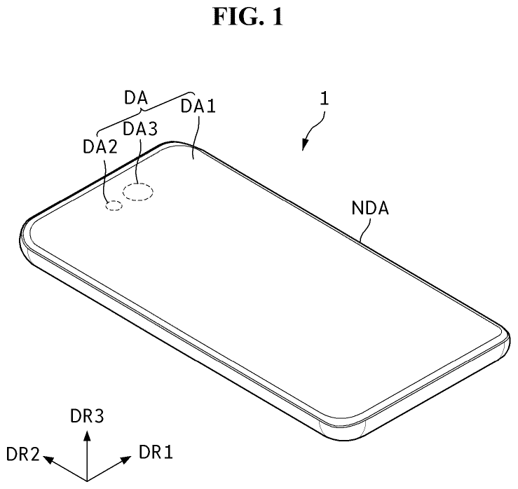

FIG. 1 is a plan view of a display device according to some embodiments of the present disclosure.

Referring to FIG. 1, an electronic device 1 displays a moving image (e.g., video images) or a still image (e.g., static images). The electronic device 1 may refer to any electronic device that provides a display screen. For example, the electronic device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

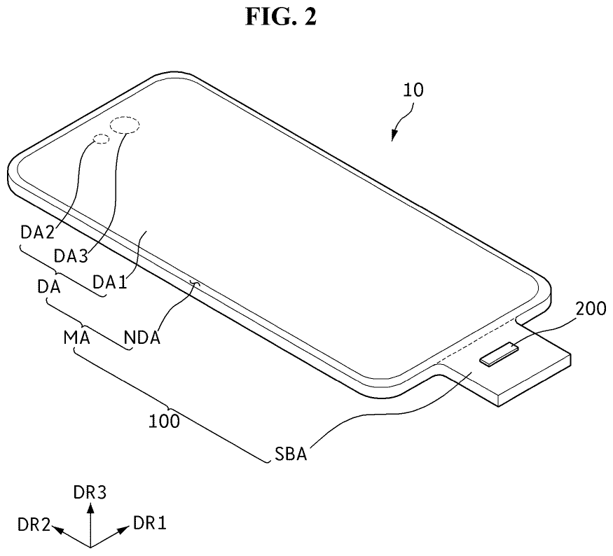

The electronic device 1 may include a display device 10 (see FIG. 2) for providing a display screen. Examples of the display device may include an inorganic light-emitting diode display device, an organic light-emitting display device, a quantum-dot light-emitting display device, a plasma display device, a field emission display device, etc. In the following description, an organic light-emitting diode display device is employed as an example of the display device, but embodiments according to the present disclosure are not limited thereto. Any other display device may be employed as long as the technical idea of the present disclosure can be equally applied.

The shape of the electronic device 1 may be modified in a variety of ways. For example, the electronic device 1 may have shapes such as a rectangle with longer lateral sides, a rectangle with longer vertical sides, a square, a quadrangle with rounded corners (vertices), other polygons, a circle, etc. The shape of a display area DA of the electronic device 1 may also be similar to the overall shape of the electronic device 1. In the example shown in FIG. 1, the electronic device 1 has a rectangular shape with the longer sides in a second direction DR2.

The electronic device 1 may include the display area DA and a non-display area NDA. In the display area DPA, images can be displayed. In the non-display area NDA, images are not displayed. The display area DPA may be referred to as an active area, while the non-display area NDA may also be referred to as an inactive area. The display area DA may generally occupy the center of the electronic device 1.

The display area DA may include a first display area DA1, a second display area DA2 and a third display area DA3. In the second display area DA2 and the third display area DA3, components for adding a variety of features to the electronic device 1 may be located. In other words, the second display area DA2 and the third display area DA3 may be referred to as component areas.

FIG. 2 is a perspective view showing a display device included in an electronic device according to some embodiments of the present disclosure.

Referring to FIG. 2, the electronic device 1 according to some embodiments of the present disclosure may include a display device 10. The display device 10 may provide a display screen where images are displayed in the electronic device 1. The display device 10 may have a shape similar to that of the electronic device 1 when viewed from the top. For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a predetermined curvature. It should be understood, however, that embodiments according to the present disclosure are not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100 and a driver circuit (or display driver) 200.

The display panel 100 may include a main area MA and a subsidiary area SBA.

The main area MA may include the display area DA including pixels for displaying images, and the non-display area NDA located around the display area DA.

The display area DA may include the first display area DA1, the second display area DA2 and the third display area DA3. The display area DA may output lights from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED).

The non-display area NDA may be located on the outer side (e.g., in a periphery or outside a footprint) of the display area DA. The non-display area NDA may be defined as the edge of the main area MA of the display panel 100. The non-display area NDA may include a gate driver that applies gate signals to gate lines, and fan-out lines that connect the display driver 200 with the display area DA.

The subsidiary area SBA may be extended from one side of the main area MA. The subsidiary area SUB may include a flexible material that can be bent, folded, or rolled. For example, when the subsidiary area SBA is bent, the subsidiary area SBA may overlap the main area MA in the thickness direction (third direction DR3). The subsidiary area SBA may include pads connected to the display driver 200. According to some embodiments, the subsidiary area SBA may be eliminated, and the display driver 200 and the pads may be located in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction as the subsidiary area SBA is bent. For another example, the display driver 200 may be mounted on a circuit board.

In addition, the display device 10 may further include a circuit board. The circuit board may be attached on the pads of the display panel 100 using an anisotropic conductive film (ACF). The circuit board may be a flexible printed circuit board (FPCB), a printed circuit board (PCB), or a flexible film such as a chip-on-film (COF).

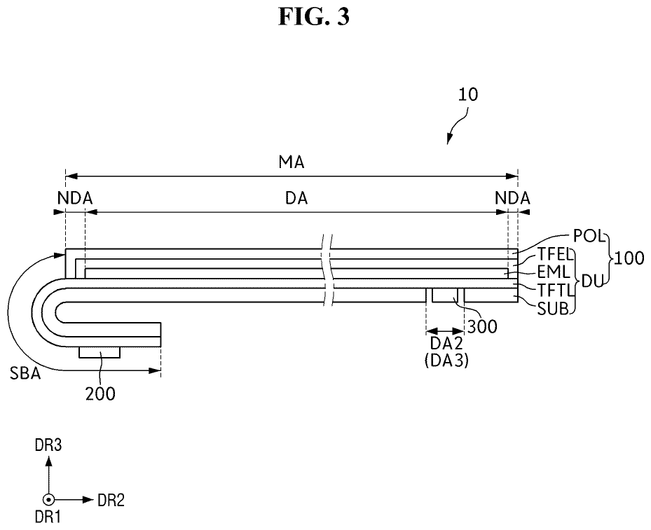

FIG. 3 is a cross-sectional view of the display device of FIG. 2 seen from the side.

Referring to FIG. 3, the display panel 100 may include a display layer DU and a polarizer POL. The display layer DU may include a substrate SUB, a thin-film transistor layer TFTL, an emission material layer EML and a thin-film encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. According to some embodiments, the substrate SUB may include a glass material or a metal material.

The thin-film transistor layer TFTL may be located on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. For example, when the gate driver is formed on one side of the non-display area NDA of the display panel 100, the gate driver may include thin-film transistors.

The thin-film transistor layer TFTL may be located in the display area DA, the non-display area NDA and the subsidiary area SBA. The thin-film transistors in each of the pixels, the gate lines, the data lines and the voltage lines in the thin-film transistor layer TFTL may be located in the display area DA. The gate control lines and the fan-out lines in the thin-film transistor layer TFTL may be located in the non-display area NDA. The lead lines of the thin-film transistor layer TFTL may be located in the subsidiary area SBA.

The emission material layer EML may be located on the thin-film transistor layer TFTL. The emission material layer EML may include a plurality of light-emitting elements each including a first electrode, a second electrode and a light emitting layer to emit light, and a pixel-defining layer for defining the pixels. The plurality of light-emitting elements in the emission material layer EML may be located in the display area DA.

According to some embodiments of the present disclosure, the light emitting layer may be an organic emissive layer containing an organic material. The light emitting layer may include a hole transporting layer, an organic light-emitting layer and an electron transporting layer. When the first electrode receives a voltage and the second electrode receives a cathode voltage through the thin-film transistors on the thin-film transistor layer TFTL, the holes and electrons may move to the organic light-emitting layer through the hole transporting layer and the electron transporting layer, respectively, such that they combine in the organic light-emitting layer to emit light.

According to some embodiments, the light-emitting elements may include quantum-dot light-emitting diodes each including a quantum-dot emissive layer, inorganic light-emitting diodes each including an inorganic semiconductor, or micro light-emitting diodes.

The thin-film encapsulation layer TFEL may cover the upper and side surfaces of the emission material layer EML, and can protect the emission material layer EML. The thin-film encapsulation layer TFEL may include at least one inorganic film and at least one organic film for encapsulating the emission material layer EML.

The display device 10 may further include an optical device 300. The optical device 300 may be located in the second display area DA2 or the third display area DA3. The optical device 300 may output or receive light in infrared, ultraviolet, and visible ranges. For example, the optical device 300 may be an optical sensor that senses light incident on the display device 10, such as a proximity sensor, an illuminance sensor, a camera sensor and an image sensor.

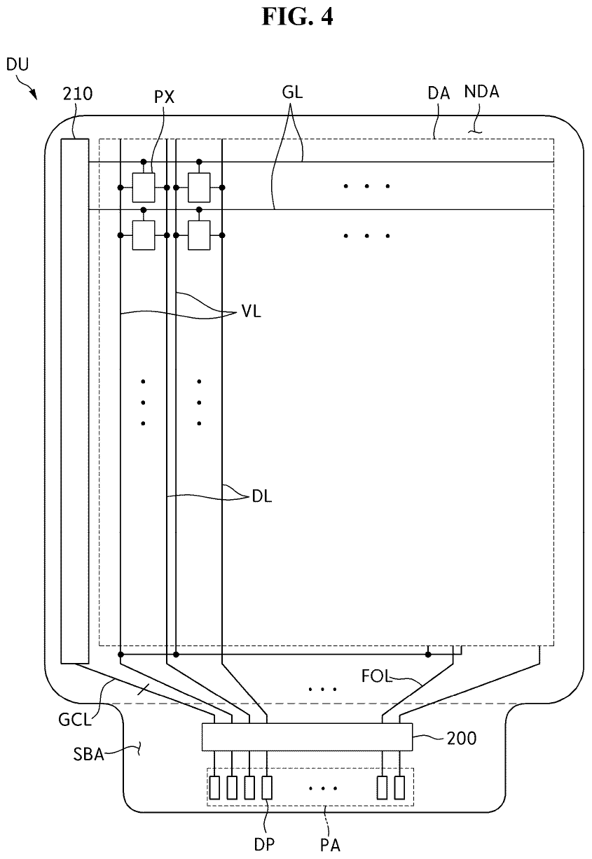

FIG. 4 is a plan view showing a display layer of a display device according to some embodiments of the present disclosure.

Referring to FIG. 4, the display layer DU may include a display area DA and a non-display area NDA.

The display area DA may be located at the center of display panel 100. In the display area DA, a plurality of pixels PX, a plurality of gate lines GL, a plurality of data lines DL and a plurality of voltage lines may be located. Each of the plurality of pixels PX may be defined as the minimum unit that outputs light.

The plurality of gate lines GL may supply the gate signals received from the gate driver 210 to the plurality of pixels PX. The plurality of gate lines GL may be extended in the first direction DR1 and may be spaced apart from one another in the second direction DR2 intersecting the first direction DR1.

The plurality of data lines DL may supply the data voltages received from the display driver 200 to the plurality of pixels PX. The plurality of data lines DL may be extended in the second direction DR2 and may be spaced apart from one another in the first direction DR1.

The plurality of voltage lines VL may apply the supply voltage received from the display driver 200 to the plurality of pixels PX. The supply voltage may be at least one of a driving voltage, an initialization voltage, a reference voltage, or a low-level voltage. The plurality of voltage lines VL may be extended in the second direction DR2 and may be spaced apart from one another in the first direction DR1.

The non-display area NDA may surround the display area DA. In the non-display area NDA, the gate driver 210, fan-out lines FOL, and gate control lines GCL may be located. The gate driver 210 may generate a plurality of gate signals based on the gate control signal, and may sequentially supply the plurality of gate signals to the plurality of gate lines GL in an order (e.g., a set or predetermined order).

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 210. The gate control line GCL may supply the gate control signal received from the display driver 200 to the gate driver 210.

The subsidiary area SBA may include the display driver 200 and a pad area PA.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a gate control signal to the gate driver 210 through the gate control lines GCL.

The pad area PA may be located at an edge of the subsidiary area SBA. The pad area PA may be electrically connected to the circuit board using a material such as an anisotropic conductive film and a self assembly anisotropic conductive paste (SAP).

The pad area PA may include a plurality of display pads DP. The plurality of display pads DP may be connected to a graphic system through the circuit board. The plurality of display pads DP may be connected to the circuit board to receive digital video data and may supply the digital video data to the display driver 200.

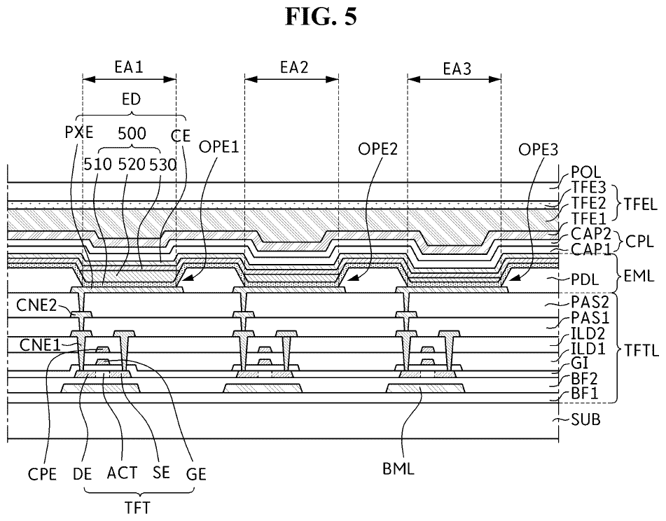

FIG. 5 is a cross-sectional view showing a portion of a display device according to some embodiments of the present disclosure. FIG. 5 is a cross-sectional view of a portion of the display device 10, for example, the substrate SUB, the thin-film transistor layer TFTL, the emission material layer EML, and the polarizer POL of the display layer DU.

Referring to FIG. 5, the substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The thin-film transistor layer TFTL may include a first buffer layer BF1, a bottom metal layer BML, a second buffer layer BF2, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2 and a second passivation layer PAS2.

The first buffer layer BF1 may be located on the substrate SUB. The first buffer layer BF1 may include an inorganic film capable of preventing permeation of air or moisture. For example, the first buffer layer BF1 may include a plurality of inorganic films stacked on one another.

The bottom metal layer BML may be located on the first buffer layer BF1. For example, the bottom metal layer BML may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films stacked on one another.

The thin-film transistor TFT may be located on the second buffer layer BF2 and may form a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE and a gate electrode GE.

The semiconductor layer ACT may be located on the second buffer layer BF2. The semiconductor layer ACT may overlap the bottom metal layer BML and the gate electrode GE in the thickness direction and may be insulated from the gate electrode GE by the gate insulator GI. The material of a portion of the semiconductor layer ACT may be made conductive to form the source electrode SE and the drain electrode DE.

The gate electrode GE may be located on the gate insulator GI. The gate electrode GE may overlap the semiconductor layer ACT with the gate insulating layer GI interposed therebetween.

The gate insulator GI may be located on the semiconductor layer ACT. For example, the gate insulator GI may cover the semiconductor layer ACT and the second buffer layer BF2, and may insulate the semiconductor layer ACT from the gate electrode GE. The gate insulator GI may include a contact hole through which the first connection electrode CNE1 passes.

The first interlayer dielectric layer ILD1 may cover the gate electrode GE and the gate insulator GI. The first interlayer dielectric layer ILD1 may include a contact hole through which the first connection electrode CNE1 passes. The contact holes of the first interlayer dielectric layer ILD1 may be connected to the contact holes of the gate insulator GI and the contact holes of the second interlayer dielectric layer ILD2.

The capacitor electrode CPE may be located on the first interlayer dielectric layer ILD1. The capacitor electrode CPE may overlap with the gate electrode GE in the thickness direction. The capacitor electrode CPE and the gate electrode GE may form a capacitance.

The second interlayer dielectric layer ILD2 may cover the capacitor electrode CPE and the first interlayer dielectric layer ILD1. The second interlayer dielectric layer ILD2 may include a contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be located on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer ILD2, the first interlayer dielectric layer ILD1, and the gate insulator GI to be in contact with the drain electrode DE of the thin-film transistor TFT.

The first passivation layer PAS1 may cover the first connection electrode CNE1 and the second interlayer dielectric layer ILD2. The first passivation layer PAS1 can protect the thin-film transistor TFT. The first passivation layer PAS1 may include a contact hole through which the second connection electrode CNE2 passes.

The second connection electrode CNE2 may be located on the first passivation layer PAS1. The second connection electrode CNE2 may electrically connect the first connection electrode CNE1 with a pixel electrode PXE of a light-emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation layer PAS2 may include a contact hole through which the pixel electrode PXE of the light-emitting element ED passes.

The emission material layer EML may be located on the thin-film transistor layer TFTL. The emission material layer EML may include a light-emitting element ED and a pixel-defining layer PDL. The light-emitting element ED may include the pixel electrode PXE, a light emitting layer 500, and a common electrode CE.

The pixel electrode PXE may be located on the second passivation layer PAS2. The pixel electrode PXE may be located in line with one of openings of the pixel-defining layer PDL. The pixel electrode PXE may be electrically connected to the drain electrode DE of the thin-film transistor TFT through the first and second connection electrodes CNE1 and CNE2.

The pixel electrode PXE may be a reflective electrode. According to some embodiments of the present disclosure, the pixel electrode PXE may include a reflective film containing silver (Ag), magnesium (Mg), aluminum (Al), platinum (Pt), palladium (Pd), gold (Au), nickel (Ni), neodymium (Nd), iridium (Ir), chromium (Cr) or a compound thereof. According to some embodiments, the pixel electrode PXE may include a transparent or translucent electrode layer located on or/and under the reflective film. The above-described transparent or transluscent electrode layer may include at least one selected from the group consisting of: indium tin oxide (ITO), indium zinc oxide (IZO), zinc oxide (ZnO), indium oxide (In2O3), indium gallium oxide (IGO), and aluminum zinc oxide (AZO). According to some embodiments, the pixel electrode PXE may have a three-layer structure of an ITO layer, an Ag layer and an ITO layer.

The light emitting layer 500 may be located on the pixel electrode PXE. For example, the light emitting layer 500 may be, but is not limited to, an organic emissive layer made of an organic material. If the light emitting layer 500 is an organic emissive layer, when the thin-film transistor TFT applies a voltage (e.g., a set or predetermined voltage) to the pixel electrode PXE of the light-emitting element ED and the common electrode CE of the light-emitting element ED receives a common voltage or cathode voltage, the holes and electrons may move to the light emitting layer 500, and they may combine in the light emitting layer 500 to emit light.

The light emitting layer 500 may include a first functional layer 510, an organic light-emitting layer 520, and a second functional layer 530. The organic light-emitting layer 520 may be located between the first functional layer 510 and the second functional layer 530. The first functional layer 510 may be located under the organic light-emitting layer 520 and adjacent to the pixel electrode PXE, and the second functional layer 530 may be located on the organic light-emitting layer 520 and adjacent to the common electrode CE.

The first functional layer 510 may include, for example, a hole transport layer HTL or may include a hole transport layer and a hole injection layer HIL. The second functional layer 530 is an element located on the organic light-emitting layer 520 and may include an electron transport layer ETL and/or an electron injection layer EIL. The second functional layer 530 is optional. In some embodiments, the second functional layer 530 may not be located.

While the organic light-emitting layer 520 is located in each opening of the pixel-defining layer PDL, each of the first functional layer 510 and the second functional layer 530 may be, for example, a common layer integrally formed to entirely cover the display area of the substrate SUB so that it entirely covers the substrate SUB, like the common electrode CE to be described later.

The common electrode CE may be located on the light emitting layer 500. For example, the common electrode CE may be implemented as an electrode common to all pixels, instead of being located as a separated electrode for each of the pixels. The common electrode CE may be located on the light emitting layer 500 in the first to third emission areas EA1, EA2 and EA3, and may be located on the pixel-defining layer PDL in the other areas than the first to third emission areas EA1, EA2 and EA3.

The common electrode CE may receive a common voltage or a low-level voltage. When the pixel electrode PXE receives the voltage equal to the data voltage and the common electrode CAT receives the low-level voltage, a potential difference is formed between the pixel electrode PXE and the common electrode CE, so that the light emitting layer 500 can emit light.

The common electrode CE may be a translucent layer such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy thereof. In some embodiments, the common electrode CE may further include a layer such as ITO, IZO, ZnO and In2O3 on the translucent layer containing the above-described material. According to some embodiments of the present disclosure, the common electrode CE may include silver (Ag), magnesium (Mg), or an alloy of silver (Ag) and magnesium (Mg).

The pixel-defining layer PDL may include a plurality of openings OPE1, OPE2 and OPE3, and may be located on the second passivation layer PAS2 and a portion of the pixel electrode PXE. The pixel-defining layer PDL may include the first opening OPE1, the second opening OPE2 and the third opening OPE3, and each of the openings OPE1, OPE2 and OPE3 is a portion of the pixel electrode PXE. As described above, the openings OPE1, OPE2 and OPE3 of the pixel-defining layer PDL may define the first to third emission areas EA1, EA2 and EA3, respectively, which may have different areas or sizes. The pixel-defining layer PDL may separate and insulate the pixel electrode PXE of one of the plurality of light-emitting diodes ED from the pixel electrode of another one of the light-emitting elements ED. The pixel-defining layer PDL may include a light-absorbing material to prevent light reflection. For example, the pixel-defining layer PDL may include a polyimide (PI)-based binder, and pigments in which red, green and blue are mixed. Alternatively, the pixel-defining layer PDL may include a cardo-based binder resin and a mixture of lactam black pigment and blue pigment. Alternatively, the pixel-defining layer PDL may include carbon black.

A capping layer CPL may be located on the common electrode CE. The capping layer CPL can protect the light-emitting elements ED by covering them on the common electrode CE. The capping layer CPL may include a stack of films. The capping layer CPL may include a first capping layer CAP1 located on the common electrode CE, and a second capping layer CAP2 located on the first capping layer CAP1.

The first capping layer CAP1 may be located between the common electrode CE and the second capping layer CAP2, and the second capping layer CAP2 may be located between the first capping layer CAP1 and the thin-film encapsulation layer TFEL. The first capping layer CAP1 may be in contact with the common electrode CE and the second capping layer CAP2, and the second capping layer CAP2 may be in contact with the first capping layer CAP1 and the thin-film encapsulation layer TFEL.

The capping layer CPL may contain LiF, an inorganic insulating material, or an organic insulating material. For example, the first capping layer CAP1 may include an inorganic insulating material. The first capping layer CAP1 may include one or more inorganic insulating materials selected from the group consisting of: aluminum oxide, titanium oxide, titanium oxide, hafnium oxide, zinc oxide, silicon oxide, silicon nitride, and silicon oxynitride. The second capping layer CAP2 may include one or more selected from the group consisting of: LiF, MgF₂, AlF₂, NaF, and AlOx.

The thin-film encapsulation layer TFEL may be located on the capping layer CPL. The thin-film encapsulation layer TFEL may include at least one inorganic encapsulation layer and at least one organic encapsulation layer. For example, the thin-film encapsulation layer TFEL may include a first encapsulation film TFE1 located on the second capping layer CAP2, a second encapsulation film TFE2 located on the first encapsulation film TFE1, and a third encapsulation film TFE3 located on the second encapsulation film TFE2, as shown in FIG. 5.

The first encapsulation film TFE1 and the third encapsulation film TFE3 may include an inorganic insulating material. For example, the inorganic insulating material may include one or more selected from the group consisting of: aluminum oxide, titanium oxide, titanium oxide, hafnium oxide, zinc oxide, silicon oxide, silicon nitride, and silicon oxynitride. In some embodiments, the first encapsulation film TFE1 and the third encapsulation film TFE3 may include an inorganic insulating layer containing a non-metallic element, such as silicon oxide, silicon nitride and silicon oxynitride. The number and type of non-metallic elements included in the first encapsulation film TFE1 may be different from the number and type of non-metallic elements included in the third encapsulation film TFE3. For example, the first encapsulation film TFE1 may include silicon nitride, and the third encapsulation film TFE3 may include silicon oxide. It should be understood, however, that the embodiments of the present disclosure are not limited thereto.

The second encapsulation film TFE2 may be used to relieve internal stress of the first encapsulation film TFE1 and/or the third encapsulation film TFE3 or to fill the gaps created by particles. The second encapsulation layer TFE2 may include a polymer-based material. Such polymer-based material may include polyethylene terephthalate, polyethylene naphthalate, polycarbonate, polyimide, polyethylene sulfonate, polyoxymethylene, polyarylate, hexamethyldisiloxane, acrylic resins (e.g., polymethyl methacrylate, polyacrylic acid, etc.) or any combination thereof.

The second encapsulation film TEF2 may be formed by applying a monomer having flowability and then curing a monomer layer using heat or light such as ultraviolet rays. Alternatively, the second encapsulation film TEF2 may be formed by applying the above-described polymer-based material.

The polarizer POL may be located on the thin-film encapsulation layer TFEL. The polarizer POL can reduce the reflection of external light to improve visibility. The polarizer POL may convert natural light or polarized light into arbitrary polarized light. For example, external light incident on the display device 10 may be converted into linearly polarized light.

The polarizer POL may be stretched in a direction. The direction in which the polarizer POL is stretched may be an absorption axis, while the direction perpendicular thereto may be a transmission axis. According to some embodiments, the transmission axis of the polarizer POL may be zero degree.

The polarizer POL may include a polymer material composed mainly of a polyvinyl alcohol (PVA) resin containing iodine or dichroic dye. It should be understood, however, that the embodiments of the present disclosure are not limited thereto. The polarizer POL may include an O-type polarizing element in which liquid-crystal compositions containing a dichroic material and a liquid-crystal compound are oriented in a certain direction, or an E-type polarizing element in which lyotropic liquid crystals are oriented in a certain direction, etc.

The light-emitting element ED located at each pixel may have a different stack structure in consideration of the wavelength of light or the material. For example, it may have a structure and a thickness that takes into account the micro-cavity distance between two electrodes depending on the wavelength of light emitted from the respective organic light-emitting layer. As the intensity of light emitted from each light-emitting element increases due to the micro-cavity effects, there may arise a problem that the viewing angle characteristics of the display device 10 change. For example, as the intensity of light emitted from each light-emitting element increases due to the micro-cavity effects, the color shift according to the viewing angle at which a user watches the display device 10 also increases, and thus the colors seen by the user change depending on the viewing angle.

Hereinafter, a method for fabricating a display device that can measure optical characteristics and then correct them after fabricating a light-emitting element ED will be disclosed.

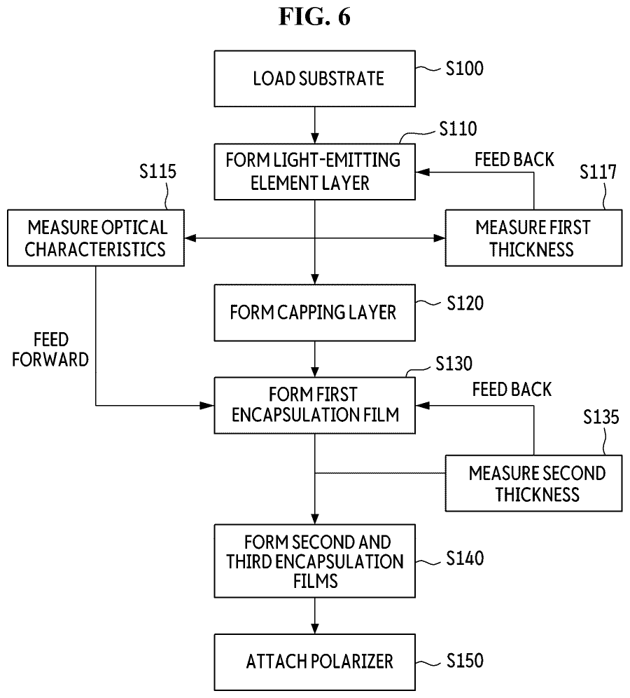

FIG. 6 is a flowchart for illustrating a method for fabricating a display device according to some embodiments of the present disclosure. Although FIG. 6 illustrates various operations in a method for fabricating a display device, embodiments according to the present disclosure are not limited thereto, and according to some embodiments, the method for fabricating the display device may include additional operations or fewer operations, or the order of operations may vary, unless otherwise stated or implied, without departing from the spirit and scope of embodiments according to the present disclosure.

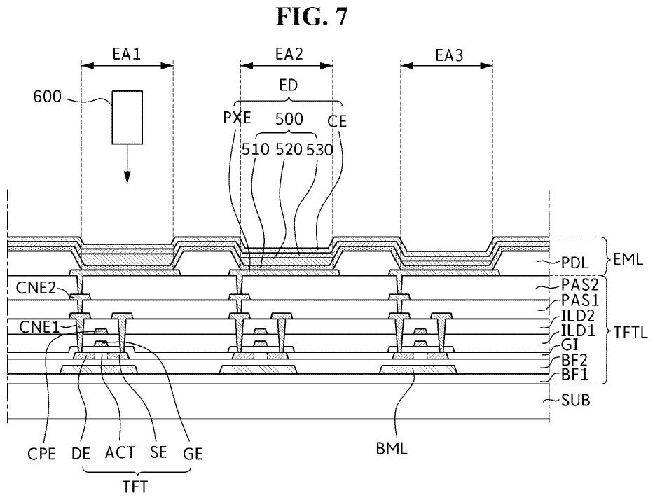

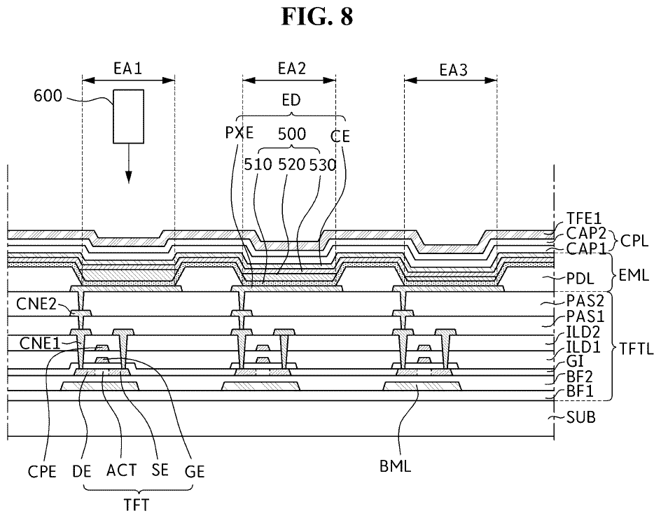

FIGS. 7 and 8 are cross-sectional views showing processing operations of a method for fabricating a display device according to some embodiments of the present disclosure.

Referring to FIG. 6, a method for fabricating a display device according to some embodiments may include: loading a substrate (operation S100), forming a light-emitting element layer (operation S110), forming a capping layer (operation S120), forming a first encapsulation film (operation S130), forming second and third encapsulation films (operation S140), and attaching a polarizer (operation S150). In addition, the method may include measuring optical characteristics (operation S115) and measuring a first thickness (operation S117) between the forming the light-emitting element layer S110 and the forming the capping layer S120, or may include measuring a second thickness (operation S135) between the forming the first encapsulation film S130 and the forming the second and third encapsulation films S140.

Referring to FIGS. 7 and 8 in conjunction with FIG. 6, the loading the substrate S100 is for loading a substrate SUB into a deposition equipment to form an emission material layer EML. On the substrate SUB, the pixel electrode PXE and the pixel-defining layer PDL of FIG. 7 may be formed. In some embodiments, the pixel electrode PXE may have a structure in which a silver (Ag) reflective layer and an ITO electrode are stacked.

Subsequently, the forming the light-emitting element layer S110 is performed. The forming the light-emitting element layer S110 may include forming a light emitting layer 500 and a common electrode CE on the pixel electrode PXE and the pixel-defining layer PDL of the loaded substrate SUB. In doing so, a first functional layer 510 and a second functional layer 530 may be formed commonly on the emission areas EA1, EA2 and EA3, and the organic light-emitting layer 520 may be formed on each of the emission areas EA1, EA2 and EA3 by being independently deposited.

According to some embodiments, the first functional layer 510 may be formed including a hole injection layer, and the second functional layer 530 may be formed including a buffer layer, a hole transport layer, and a hole injection layer. The organic light-emitting layer 520 may include two or more layers stacked on one another. For example, the organic light-emitting layer 520, which emits red light, may include two layers, the organic light-emitting layer 520, which emits green light, may include three layers, and the organic light-emitting layer 520, which emits blue light, may include two layers. It is, however, to be understood that embodiments according to the present disclosure are not limited thereto.

The common electrode 173 may be deposited commonly in the emission areas EA1, EA2 and EA3. Accordingly, the forming the light-emitting element layer S110 may include forming the light emitting layer 500 and the common electrode CE to fabricate an emission material layer EML including a plurality of light-emitting elements ED.

Subsequently, the measuring optical characteristics S115 and the measuring the first thickness S117 of the emission material layer EML are performed. The order of the measuring the optical characteristics S115 and the measuring the first thickness S117 is not particular limited herein. For example, the measuring optical characteristics S115 may be performed first and then the measuring the first thickness S117 may be performed, or vice versa.

The measuring the optical characteristics S115 may include measuring white angle difference (WAD) distribution by turning on the light-emitting element ED of the emission material layer EML formed on the substrate SUB. The WAD distribution refers to white light emitted by a light-emitting element ED on the 1976 color coordinate system. In doing so, the experiment is repeated by changing the viewing angle at which a user watches the light-emitting element ED, and the color that appears in each experiment is displayed on the color coordinate system. The distribution of such points on the color coordinate system is referred to as the WAD distribution.

The color characteristics of the light-emitting element ED may vary depending on the shape of the WAD distribution on the color coordinate system. For example, if the WAD distribution is distributed over a green or red region, the white color may look red on the display device 10. The WAD distribution may be measured using a spectrometer 600.

After measuring the WAD distribution, it is determined whether the WAD distribution is defective. For example, it is determined that the WAD distribution is normal if the WAD distribution lies within the specification. It is determined that the WAD distribution is defective if it lies outside the specification, and such results may be fed forward for correcting the WAD distribution in a subsequent process. As used herein, the feeding forward means that correcting the WAD distribution by adjusting the thickness of the first encapsulation film TFE1, i.e., decreasing or increasing the thickness in a subsequent process for forming the first encapsulation film TFE1, for example.

In the color coordinate system, based on the vertical axis, the points having a (−) value in the direction (y-axis) away from 0 (zero) become blue, while the points having a (+) value in the direction (y-axis) away from 0 (zero) become green. In addition, based on the horizontal axis, the points having a (−) value in the direction (x-axis) away from 0 (zero) become blue, while the points having a (+) value in the direction (x-axis) away from 0 (zero) become red.

According to some embodiments, when the WAD distribution partially deviates from the normal specification range to the red region, the thickness of the first encapsulation film TFE1 may be increased to move the WAD distribution to the blue region. On the contrary, when the WAD distribution partially deviates from the normal specification range to the green region, the thickness of the first encapsulation film TFE1 may be decreased to move the WAD distribution to the red region.

According to some embodiments, after the emission material layer EML has been fabricated, the WAD distribution may be checked in the measuring the optical characteristics S115 and then the thickness of the first encapsulation film TFE1 may be adjusted to correct the WAD distribution.

The measuring the first thickness S117 may include measuring the thickness of the emission material layer EML. For example, the measuring the first thickness S117 may include measuring the thickness of the light emitting layer 500 of the emission material layer EML. In doing so, it may be checked whether the light emitting layer 500 is properly formed as designed in each of the emission areas EA1, EA2 and EA3 to utilize the micro-cavity effects.

The measuring the first thickness S117 may include measuring the thickness of each of the first functional layer 510, the organic light-emitting layer 520 and the second functional layer 530 of the light emitting layer 500 using an ellipsometer.

After the measuring the thickness of the light emitting layer 500 in the measuring the first thickness S117, it is determined whether it is good or bad by comparing the thickness of each layer input when forming the light emitting layer 500 with the actually formed thickness, which may be fed back to the forming the light-emitting element layer S110. For example, if the thickness of the organic light-emitting layer 520 is thinner than designed, a feedback signal to deposit thicker may be provided.

Subsequently, the forming the capping layer S120 is performed. The forming the capping layer S120 may include forming a capping layer CPL including a first capping layer CAP1 and a second capping layer CAP2 on the emission material layer EML. According to some embodiments of the present disclosure, the first capping layer CAP1 may include silicon oxide or silicon nitride, and the second capping layer CAP2 may include LiF.

Subsequently, the forming the first encapsulation film S130 is performed. The forming the first encapsulation film S130 may include forming the first encapsulation film TFE1 of the thin-film encapsulation layer TFEL. The first encapsulation film TFE1 may have a thickness ranging from approximately 600 nm to 2,200 nm in order to protect the emission material layer EML from moisture and maintain adhesive properties.

According to some embodiments, the thickness of the first encapsulation film TFE1 may be adjusted based on the feed forward signal in the measuring the optical characteristics S115. For example, the first encapsulation film TFE1 may be formed by adjusting (or correcting) the thickness of the first encapsulation film TFE1 in a facility (e.g., CVD equipment) that forms the first encapsulation film TFE1.

In order to adjust the thickness of the first encapsulation film TFE1 based on the feed forward signal, the thickness of the first encapsulation film TFE1 may be checked by looking up a prepared correction table. In the correction table, the degree of movement of the WAD distribution depending on the thickness of the first encapsulation film TFE1 may be written as numerical values, which are obtained empirically. For example, it is originally designed that the first encapsulation film TFE1 should be formed to the thickness of 220 nm, but the thickness of the first encapsulation film TFE1 may be increased to 230 nm based on the feed forward signal.

Subsequently, the measuring the second thickness S135 is performed. The measuring the second thickness S135 may include measuring the thickness of the first encapsulation film TFE1. In doing so, it may be checked whether the first encapsulation film TFE1 has been formed properly to a desired thickness based on the feed forward signal.

After the measuring the thickness of the first encapsulation film TFE1 in the measuring the second thickness S135, it is determined whether it is good or bad, which may be fed back to the forming the first encapsulation film S130. For example, if the thickness of the first encapsulation film TFE1 is different from the corrected input value, a feedback signal may be provided to adjust the deposition process conditions of the CVD equipment.

Subsequently, the forming the second and third encapsulation films S140 are performed. The forming the second and third encapsulation films S140 may include forming the second encapsulation film TFE2 and the third encapsulation film TFE3 of the thin-film encapsulation layer TFEL. The second encapsulation film TFE2 may be formed of a polymer-based material via a solution process. For example, the solution process may include, spin coating, slit coating, inkjet printing, etc. The third encapsulation film TFE3 may be deposited using the above-described inorganic insulating material using a CVD equipment.

Subsequently, the attaching a polarizer S150 is performed. The attaching the polarizer S150 may include attaching the polarizer POL on the thin-film encapsulation layer TFEL. After the polarizer POL has been attached, the display device 10 according to some embodiments can be completed.

As described above, the method for fabricating the display device 10 according to some embodiments may include measuring the WAD distribution after fabricating the emission material layer EML; and adjusting the thickness of the first encapsulation film TFE1 by sending a feedforward signal. In this manner, the color difference depending on the viewing angle can be mitigated by adjusting the WAD distribution of the display device 10.

It should be noted that although the thickness of the first encapsulation film TFE1 is adjusted according to some embodiments, a similar effect can be achieved by adjusting the refractive index by changing the film quality of the first encapsulation film TFE1. Herein, changing the film quality may mean adjusting the component ratio of the first encapsulation film TFE1.

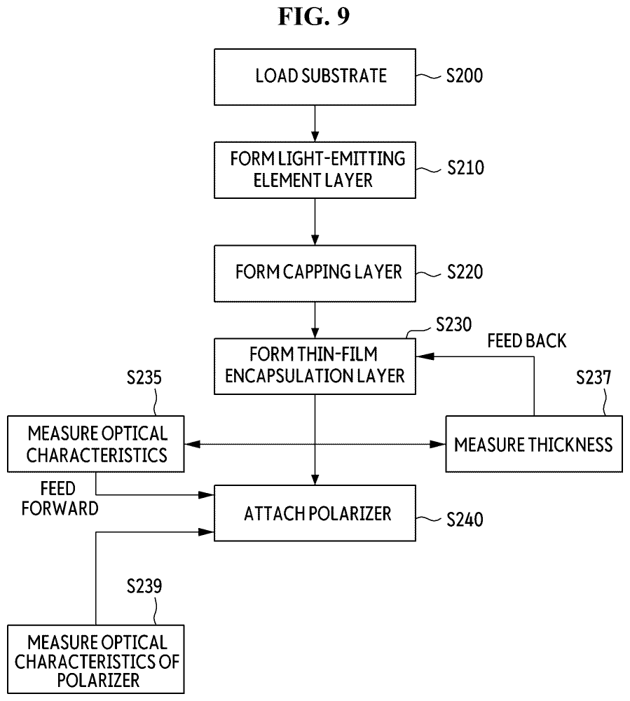

FIG. 9 is a flowchart for illustrating a method for fabricating a display device according to some embodiments. Although FIG. 9 illustrates various operations in a method for fabricating a display device, embodiments according to the present disclosure are not limited thereto, and according to some embodiments, the method for fabricating the display device may include additional operations or fewer operations, or the order of operations may vary, unless otherwise stated or implied, without departing from the spirit and scope of embodiments according to the present disclosure.

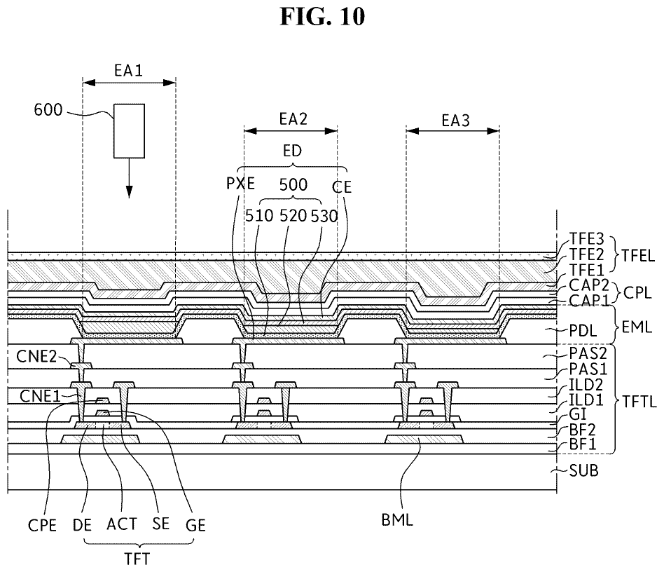

FIG. 10 is a cross-sectional view for illustrating processing operations of a method for fabricating a display device according to some embodiments of the present disclosure.

The embodiments of FIGS. 9 and 10 is different from the above-described embodiments of FIGS. 6 to 8 in that optical characteristics are measured after the thin-film encapsulation layer TFEL has been formed, and a feed forward signal is sent to the attaching the polarizer to adjust the WAD distribution. The following description will focus on the differences and some redundant description may be omitted.

As shown in FIG. 9, a method for fabricating a display device according to some embodiments may include loading a substrate (operation S200), forming a light-emitting element layer (operation S210), forming a capping layer (operation S220), forming a thin-film encapsulation layer (operation S230), and attaching a polarizer (operation S240). In addition, the method may include measuring optical characteristics (operation S235) and measuring a thickness (operation S237) between the forming thin-film encapsulation layer S230 and the attaching the polarizer S240, and may include measuring optical characteristics of the polarizer S239 prior to the attaching the polarizer S240.

The loading the substrate S200, the forming the light-emitting element layer S210, the forming the capping layer S220 and the forming the thin-film encapsulation layer S230 are identical to the loading the substrate S100, the forming the light-emitting element layer S110, the forming the capping layer S120, the forming the first encapsulation film S130 and the forming the second and third encapsulation films S140 shown in FIG. 6; and, therefore, some redundant descriptions may be omitted

The measuring the optical characteristics S235 performed after the forming the thin-film encapsulation layer S230 may include measuring the WAD distribution by turning on the light-emitting element ED of the emission material layer EML formed on the substrate SUB. After measuring the WAD distribution, it is determined whether the WAD distribution is defective. For example, it is determined that the WAD distribution is normal if the WAD distribution lies within the specification. It is determined that the WAD distribution is defective if it lies outside the specification, and such results may be fed forward for correcting the WAD distribution in a subsequent process. As used herein, the feeding forward means that correcting the WAD distribution by selecting a polarizer POL having particular optical characteristics and attaching it in a subsequent process of attaching the polarizer POL, for example.

The measuring the thickness S237 may include measuring the thickness of the thin-film encapsulation layer TFEL. For example, the measuring the thickness S237 may include measuring the thicknesses of the first to third encapsulation films TFE1, TFE2 and TFE3 of the thin-film encapsulation layer TFEL. In doing so, it may be checked whether the first to third encapsulation films TFE1, TFE2 and TFE3 of the thin-film encapsulation layer TFEL are properly formed as designed.

The measuring the thickness S237 may include measuring the thickness of each of the first to third encapsulation films TFE1, TFE2 and TFE3 of the thin-film encapsulation layer TFEL using an ellipsometer.

The measuring the thickness S237 may include measuring the thicknesses of the first to third encapsulation films TFE1, TFE2 and TFE3 of the thin-film encapsulation layer TFEL, and then determining whether the thickness of each of the layers is good or bad, which may be fed back to the forming the thin-film encapsulation layer S230. For example, if the thickness of the thin-film encapsulation layer TFEL is measured differently from the design, a feedback signal may be provided to correct it.

In the measuring the optical characteristics of a polarizer S239, a polarizer having particular optical characteristics may be selected based on the feed forward signal in a subsequent process of attaching a polarizer POL. Polarizers may have different optical characteristics depending on the fabrication process conditions. For example, the polarizers may represent a bluish, reddish or greenish color by adjusting the concentration of iodine ions or depending on process conditions such as elongation ratio and drying time The optical characteristics of such polarizers POL may be measured by a spectrometer, etc. and may be expressed as color coordinates and chromaticity deviations (duv).

The WAD distribution fed forward from the measuring optical characteristic S235 previously performed is determined, and if it is determined that the WAD distribution is outside the specification, certain color coordinates and chromaticity deviations are required to correct the WAD distribution to the inside of the specification. According to some embodiments, the optical characteristics of a polarizer POL may be used to correct WAD dispersion in a subsequent process.

In the measuring optical characteristics of a polarizer S239, a polarizer POL having particular color coordinates and chromaticity deviations may be selected based on the received feed forward signal. For example, when the WAD distribution is partially located in a red region, polarizers having bluish color coordinates may be first selected to move the WAD distribution to a blue region. Then, if the chromaticity deviations required for moving the WAD distribution is approximately +0.003, a polarizer having a chromaticity deviation of approximately +0.003 may be second selected. In this manner, a polarizer with bluish color coordinates and a chromaticity deviation of approximately +0.003 may be selected.

Subsequently, the attaching the polarizer S240 is performed. The attaching the polarizer S240 may include attaching the previously selected polarizer POL on the thin-film encapsulation layer TFEL to finally fabricate the display device 10.

As described above, according to some embodiments, the WAD distribution of the display device 10 formed up to the thin-film encapsulation layer TFEL is checked in the measuring optical characteristics S235 before attaching the polarizer POL, and then the polarizer POL is selected and attached, thereby correcting the WAD distribution of the display device 10. Accordingly, the display quality of the display device 10 can be improved.

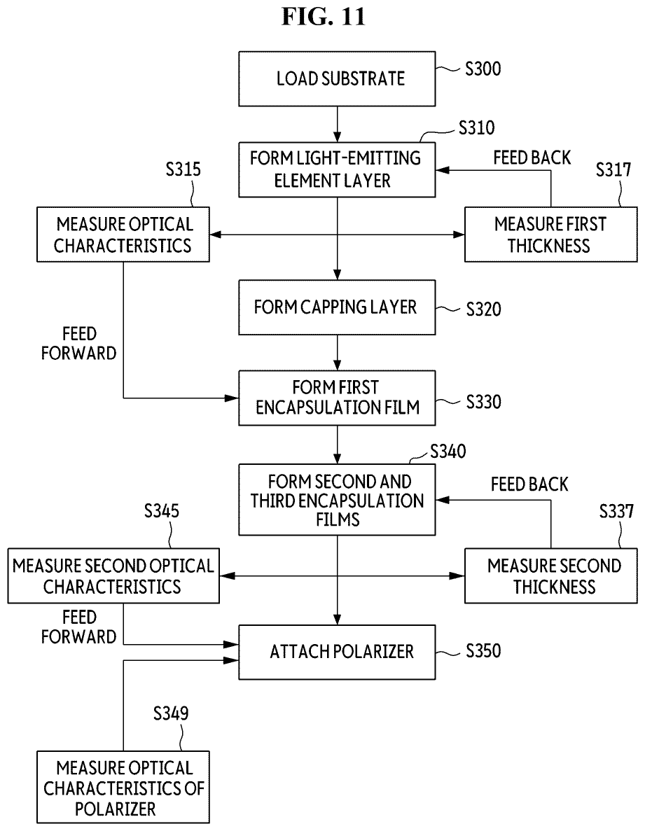

FIG. 11 is a flowchart for illustrating a method for fabricating a display device according to some embodiments of the present disclosure. Although FIG. 11 illustrates various operations in a method for fabricating a display device, embodiments according to the present disclosure are not limited thereto, and according to some embodiments, the method for fabricating the display device may include additional operations or fewer operations, or the order of operations may vary, unless otherwise stated or implied, without departing from the spirit and scope of embodiments according to the present disclosure.

The embodiments of FIG. 11 is different from the above-described embodiments of FIGS. 6 to 10 in that the methods according to some embodiments of FIGS. 6 and 9 are combined.

As shown in FIG. 11, a method for fabricating a display device according to some embodiments may include: loading a substrate (operation S300), forming a light-emitting element layer (operation S310), forming a capping layer (operation S320), forming a first encapsulation film (operation S330), forming second and third encapsulation films (operation S340), and attaching a polarizer (operation S350). In addition, the method may include measuring first optical characteristics (operation S310) and measuring a first thickness (operation S317) between the forming the light-emitting element layer S310 and the forming the capping layer S320, and may include measuring second optical characteristics (operation S345), measuring a second thickness (operation S347) and measuring optical characteristics of a polarizer (operation S349) between the forming the second and third encapsulation films S340 and the attaching the polarizer S350.

The loading the substrate S300, the forming the light-emitting element layer S310, the forming the capping layer S320, the measuring the first optical characteristics S315 and the measuring the first thickness S317 are identical to the loading the substrate S100, the forming the light-emitting element layer S110, the forming the capping layer S120, the measuring the optical characteristics S115 and the measuring the first thickness S117 of FIG. 6 described above, respectively.

The forming the first encapsulation film S330, the forming the second and third encapsulation films S340, the attaching the polarizer S350, the measuring the second optical characteristics S345, the measuring the second thickness S347 and the measuring the optical characteristics of the polarizer S349 are identical to the forming the thin-film encapsulation layer S230, the attaching the polarizer S240, the measuring optical characteristics S235, the measuring the thickness S237 and the measuring the optical characteristics of the polarizer S239 of FIG. 9 described above.

according to some embodiments, the measuring the first optical characteristics S315 is performed after the forming the light-emitting element layer S310, and a feed forward signal is sent to first correct the WAD distribution in the forming the first encapsulation film S330. In addition, the measuring the second optical characteristics S345 is performed after the forming the encapsulation layer, and a feed forward signal is sent to second correct the WAD distribution in the attaching the polarizer S350. In this manner, the display quality of the display device 10 can be improved by correcting the WAD distribution twice.

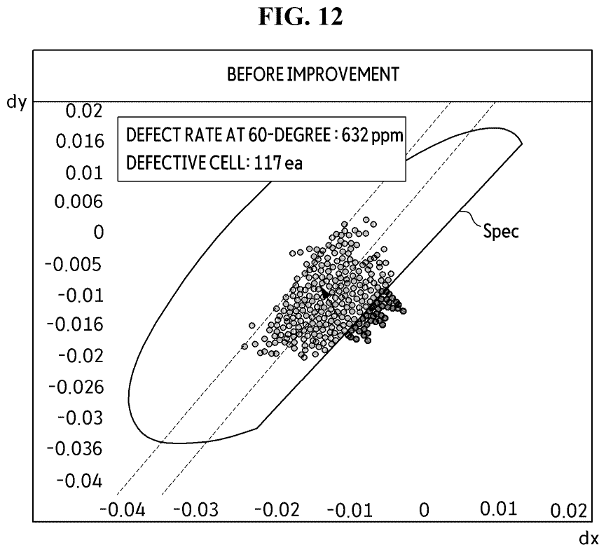

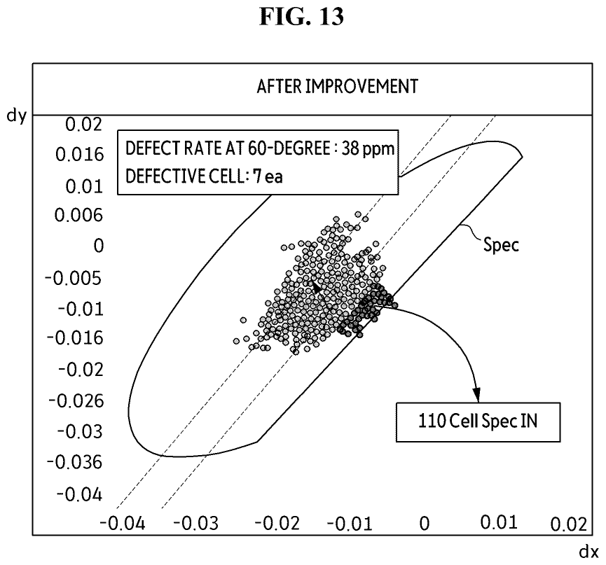

FIG. 12 is an xy color coordinate system showing the WAD distributions of display devices before improvement. FIG. 13 is an xy color coordinate system showing the WAD distributions of display devices after improvement.

FIG. 12 shows the results of simulating WAD distributions at a 60-degree viewing angle of display devices without employing the method for fabricating a display device according to FIGS. 6 to 11 described above. FIG. 13 shows the results of simulating WAD distributions at a 60-degree viewing angle of display devices employing the method for fabricating a display device according to FIGS. 6 to 8 described above.

As shown in FIG. 12, the defect rate was 632 ppm and there were approximately 117 defective display devices. As used herein, defective display devices refer to display devices having WAD distribution outside the specification.

In contrast, as shown in FIG. 13, when the WAD distribution was corrected by adjusting the thickness of the first encapsulation film (e.g., increasing the thickness of the first encapsulation film), the defect rate was 38 ppm and there were approximately 7 defective display devices.

It can be seen from the above simulation results that the display quality can be improved by correcting the WAD distribution of the display device by the method for fabricating a display device according to some embodiments of the present disclosure.

The display device according to one embodiment of the present disclosure can be applied to various electronic devices. The electronic device according to the one embodiment of the present disclosure includes the display device described above, and may further include modules or devices having additional functions in addition to the display device.

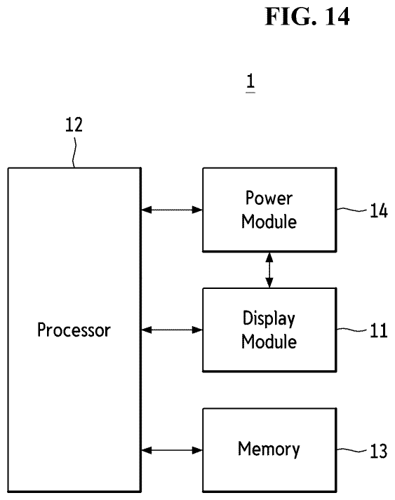

FIG. 14 is a block diagram of an electronic device according to one embodiment of the present disclosure.

Referring to FIG. 14, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

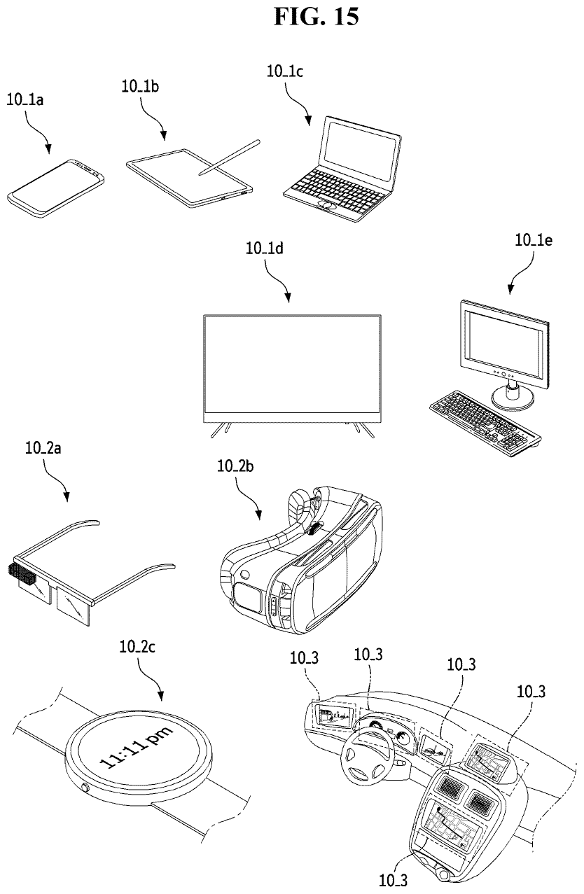

FIG. 15 is a schematic diagram of an electronic device according to various embodiments of the present disclosure.

Referring to FIG. 15, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the disclosed embodiments without substantially departing from the principles of the present invention. Therefore, the disclosed embodiments of the invention are used in a generic and descriptive sense only and not for purposes of limitation.

What is claimed is:

1. A method for fabricating a display device, the method comprising:
loading a substrate;
forming a light-emitting element layer on the substrate;
forming a capping layer on the light-emitting element layer;
forming a first encapsulation film on the capping layer;
forming a thin-film encapsulation layer by forming second and third encapsulation films on the first encapsulation film;
attaching a polarizer on the thin-film encapsulation layer; and
measuring first optical characteristics of the light-emitting element layer prior to the forming the capping layer,
wherein measuring the first optical characteristics comprises measuring and determining a white angle difference (WAD) distribution of the light-emitting element layer to send a feed forward signal in order to adjust a thickness of the first encapsulation film.

2. The method of claim 1, wherein loading the substrate comprises loading the substrate having a plurality of pixel electrodes formed thereon into a deposition equipment.

3. The method of claim 2, wherein forming the light-emitting element layer comprises forming a light emitting layer on the pixel electrodes and forming a common electrode on the light emitting layer.

4. The method of claim 1, wherein measuring the first optical characteristics comprises measuring the WAD distribution of white light of the light-emitting element layer.

5. The method of claim 1, wherein measuring the first optical characteristics comprises:
determining the WAD distribution does not lie within a normal specification range; and
sending a feed forward signal to adjust the thickness of the first encapsulation film in response to determining that the WAD distribution does not lie within a normal specification range.

6. The method of claim 5, further comprising, in response to determining that the WAD distribution partially deviates from the normal specification range to a particular color region, adjusting the thickness of the first encapsulation film to move the WAD distribution to the normal specification range.

7. The method of claim 6, wherein the adjusting the thickness of the first encapsulation film comprises increasing or decreasing the thickness of the first encapsulation film.

8. The method of claim 1, wherein the measuring the first optical characteristics comprises: using a spectroscope.

9. The method of claim 1, further comprising:
measuring a thickness of the light-emitting element layer prior to the forming the capping layer,
wherein the light-emitting element layer comprises a light emitting layer comprising a first functional layer, an organic light-emitting layer, and a second functional layer.

10. The method of claim 9, wherein the measuring the thickness of the light-emitting element layer comprises: measuring a thickness of each of the first functional layer, the organic light-emitting layer and the second functional layer and comparing input thicknesses with the actually formed thicknesses to send a feedback signal to the forming the light-emitting element layer.

11. The method of claim 1, further comprising: measuring second optical characteristics of the light-emitting element layer and measuring optical characteristics of the polarizer between the forming the thin-film encapsulation layer and the attaching the polarizer.

12. The method of claim 11, wherein measuring the second optical characteristics comprises measuring the WAD distribution of white light of the light-emitting element layer on the thin-film encapsulation layer.

13. The method of claim 12, further comprising, in response to determining that the WAD distribution partially deviates from a normal specification range to a particular color region, selecting polarizers prepared in the measuring the optical characteristics of the polarizer to move the WAD distribution to the normal specification range.

14. The method of claim 13, wherein the prepared polarizers are selected by considering color coordinates and chromaticity deviations.

15. A method for fabricating a display device, the method comprising:
loading a substrate;
forming a light-emitting element layer on the substrate;
forming a capping layer on the light-emitting element layer;
forming a thin-film encapsulation layer on the capping layer;
attaching a polarizer on the thin-film encapsulation layer; and
measuring optical characteristics of the light-emitting element layer and measuring optical characteristics of a polarizer between the forming the thin-film encapsulation layer and the attaching the polarizer,
wherein measuring the optical characteristics of the light-emitting element layer comprises measuring and determining a white angle difference (WAD) distribution of the light-emitting element layer to send a feed forward signal in order to select from among a plurality of prepared polarizers.

16. The method of claim 15, wherein measuring the optical characteristics of the light-emitting element layer comprises measuring the WAD distribution of white light of the light-emitting element layer on the thin-film encapsulation layer.

17. The method of claim 16, further comprising, in response to determining that the WAD distribution partially deviates from a normal specification range to a particular color region, selecting the prepared polarizers to move the WAD distribution to the normal specification range.

18. The method of claim 17, wherein the prepared polarizers in the measuring the optical characteristics of the polarizer are selected by considering color coordinates and chromaticity deviations.

19. The method of claim 15, further comprising:
measuring a thickness of the thin-film encapsulation layer prior to the attaching the polarizer.

20. The method of claim 19, wherein measuring the thickness of the light-emitting element layer comprises:
measuring the thickness of the thin-film encapsulation layer; and
comparing an input thickness with an actually formed thickness to send a feedback signal to the forming the thin-film encapsulation layer.

21. An electronic device comprising:
a display device configured to provide an image;
a processor configured to provide an image data signal to the display device;
a memory configured to store a data information for operation; and
a power moduel configured to generate power,
wherein the display device is manufactured by:
loading a substrate;
forming a light-emitting element layer on the substrate;
forming a capping layer on the light-emitting element layer;
forming a first encapsulation film on the capping layer;
forming a thin-film encapsulation layer by forming second and third encapsulation films on the first encapsulation film;
attaching a polarizer on the thin-film encapsulation layer; and
measuring first optical characteristics of the light-emitting element layer prior to the forming the capping layer,
wherein measuring the first optical characteristics comprises measuring and determining a white angle difference (WAD) distribution of the light-emitting element layer to send a feed forward signal in order to adjust a thickness of the first encapsulation film.
